(19) United States
(12) Patent Application Publication
(10) Pub. No.: US 2024/0347669 A1
(43) Pub. Date: Oct. 17, 2024

(54) SEMICONDUCTOR STACK, LIGHT-EMITTING ELEMENT, LIGHT-EMITTING PACKAGE AND LIGHT-EMITTING DEVICE

(71) Applicant: EPISTAR CORPORATION, Hsinchu (TW)

(72) Inventors: Feng-Wen HUANG, Hsinchu (TW); Yueh-Chern LIN, Hsinchu (TW)

(21) Appl. No.: 18/633,766

(22) Filed: Apr. 12, 2024

(30) Foreign Application Priority Data
Apr. 12, 2023 (TW) 112113618

(51) Int. Cl. H01L 33/06; H01L 25/075; H01L 33/24; H01L 33/32

(52) U.S. Cl. CPC H01L 33/06; H01L 33/24; H01L 33/32; H01L 25/0753

(57) ABSTRACT

A semiconductor stack includes a first semiconductor structure, a second semiconductor structure and an active structure. The active structure includes a first well set, a second well set and a plurality of barriers. The first well set is disposed on the first semiconductor structure and includes one or multiple first wells. The second well set is disposed between the first well set and the second semiconductor structure and includes one or multiple second wells. The plurality of barriers is arranged alternately with the one or multiple first wells and the one or multiple second wells. The first well has a first thickness. The second well has a second thickness different from the first thickness. The one or multiple first wells and the one or multiple second wells include AlₓIn_{y}Ga_{1-x-y}N respectively, wherein 0≤x≤1, 0≤y≤1, 0≤1−x−y<1.

### CROSS-REFERENCE TO RELATED APPLICATIONS

### Technical Field

This disclosure claims the right of priority of TW application Ser. No. 11/211,3618 filed on Apr. 12, 2023, and the content of which is hereby incorporated by reference in its entirety.

### BACKGROUND

The present disclosure relates to a semiconductor stack, in particular, a semiconductor stack including wells having different thicknesses.

### Description of the Related Art

The light-emitting diode (LED) is a sort of solid-state semiconductor element, which has the advantages of low power consumption, low heat generation, long lifetime, shockproof, small size, high response speed, and good optical-electrical characteristics like stable emission wavelength. Therefore, light-emitting diodes have been widely applied to household appliances, equipment indicator lights, optoelectronic products, and so forth.

### SUMMARY

A semiconductor stack includes a first semiconductor structure, a second semiconductor structure and an active structure between the first semiconductor structure and the second semiconductor structure. The active structure includes a first well set, a second well set and a plurality of barriers. The first well set is disposed on the first semiconductor structure and includes one or multiple first wells. The second well set is disposed between the first well set and the second semiconductor structure and includes one or multiple second wells. The plurality of barriers is arranged alternately with the one or multiple first wells and the one or multiple second wells. Each first well has a first thickness. Each second well has a second thickness different from the first thickness. The one or multiple first wells and the one or multiple second wells include AlₓIn_{y}Ga_{1-x-y}N respectively, wherein 0≤x≤1, 0≤y≤1, 0≤1−x−u<1.

### BRIEF DESCRIPTION OF THE DRAWINGS

FIG. 1 is a schematic cross-sectional view of a semiconductor stack 1E in accordance with an embodiment of the present application.

FIG. 2 is an enlarged view of a schematic cross-section of the active structure 130 of the semiconductor stack 1E in accordance with an embodiment of the present application.

FIG. 3 is a schematic enlarged cross-sectional view of an active structure 131 of the semiconductor stack 1E in accordance with an embodiment of the present application.

FIGS. 4 and 5 respectively show simulation curves of light-emitting intensity of a semiconductor stack in accordance with an embodiment of the present application and a semiconductor stack in accordance with a comparative example.

FIG. 6 is a schematic enlarged cross-sectional view of an active structure 132 of the semiconductor stack 1E in accordance with an embodiment of the present application.

FIG. 7 shows a simulation curve of light-emitting intensity of a semiconductor stack in accordance with an embodiment of the present application and a semiconductor stack in accordance with a comparative example.

FIG. 8 is a schematic cross-sectional view of a light-emitting device 1C in accordance with an embodiment of the present application.

FIG. 9 is a schematic cross-sectional view of a light-emitting device 2C in accordance with an embodiment of the present application.

FIG. 10 is a schematic cross-sectional view of a light-emitting package 1P in accordance with an embodiment of the present application.

FIG. 11 is a schematic cross-sectional view of a light-emitting package 2P in accordance with an embodiment of the present application.

FIG. 12 is a schematic cross-sectional view of a light-emitting package 3P in accordance with an embodiment of the present application.

FIG. 13 is a schematic cross-sectional view of a light-emitting apparatus 1A in accordance with an embodiment of the present application.

### DETAILED DESCRIPTION OF THE EMBODIMENTS

The following embodiments will be described with reference to the accompanying drawings. In the description or drawings, similar or identical parts are labeled with the same reference numeral. In the drawings, the shape or thickness of the components may be enlarged or reduced. It should be noted that elements known by those skilled in the art may be omitted in the drawings or the description. In the drawings, similar components are indicated by similar reference numerals. The following descriptions and accompanying drawings are simply provided for illustration instead of limitation. It may be expected that components and features in an embodiment may be beneficially incorporated in another embodiment without further recitation. In addition, other layers/structures or steps may be incorporated in the following embodiments. For example, a description of “forming a second layer/structure on a first layer/structure” may include an embodiment which the first layer/structure directly contacts the second layer/structure, or an embodiment which the first layer/structure indirectly contacts the second layer/structure, namely other layers/structures between the first layer/structure and the second layer/structure. In addition, the spatially relative relationship between the first layer/structure and the second layer/structure may be varied depending on the operation or usage of the device, the first layer/structure is not limited to a single layer or a single structure, and the first layer may include sub-layers, and the first structure may include multiple sub-structures.

In addition, spatially relative terms, such as “beneath,” “below,” “lower,” “above,” “upper”, “top”, “bottom” and the like, may be used herein for ease of description to describe one element or feature's relationship to another element(s) or feature(s) as illustrated in the drawings. The spatially relative terms are also used to describe the possible orientations of a semiconductor stack and light-emitting element in use or operation in addition to the orientation depicted in the drawings. The apparatus may be otherwise oriented (rotated 90 degrees or at other orientations) and the spatially relative descriptors used herein may likewise be interpreted accordingly.

In the present application, if not specifically mention, the general expression of AlGaN means AlₐGa₍₁₋ₐ₎N, wherein 0≤a≤1; the general expression of InGaN means In_{b}Ga_{(1-b)}N, wherein 0≤b>1; the general expression of AlInGaN means Al_{c}In_{d}Ga_{(1-c-d)}N, wherein 0≤c≤1, 0≤d≤1. The content of the element can be adjusted for different purposes, such as, but not limited to, adjusting the energy gap or the peak wavelength of the light emitted from the semiconductor stack.

The compositions and dopants of each layer in the semiconductor stack of the present application can be determined by any suitable means, such a secondary ion mass spectrometer (SIMS).

The thickness of each layer in the semiconductor stack disclosed in the present application may be analyzed by suitable means, such as transmission electron microscopy (TEM) or scanning electron microscope (SEM), thereby corresponding to, for example, the depth position of each layer on the SIMS map.

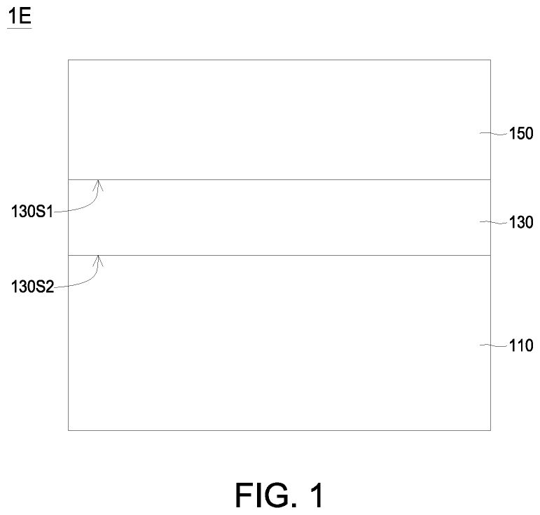

FIG. 1 is a schematic cross-sectional view of a semiconductor stack 1E in accordance with an embodiment of the present application. The semiconductor stack 1E includes a first semiconductor structure 110, a second semiconductor structure 150 and an active structure 130 formed between the first semiconductor structure 110 and the second semiconductor structure 150. In an embodiment, the first semiconductor structure 110 includes a first conductivity-type dopant, and the second semiconductor structure 150 includes a second conductivity-type dopant. By doping the first and second conductivity-type dopants into the first semiconductor structure 110 and the second semiconductor structure 150 respectively, the first semiconductor structure 110 and the second semiconductor structure 150 may have different conductivity-types, electric properties, polarities or are respectively used to provide electrons or holes. In an embodiment, the first conductivity-type dopant and the second conductivity-type dopant may be n-type dopant or p-type dopant respectively. In an embodiment, the n-type dopant includes a Group IV element, such as silicon, and the p-type dopant includes a Group II element, such as magnesium. In an embodiment, the first semiconductor structure 110 include n-type semiconductor layers, and the second semiconductor structure 150 includes p-type semiconductor layers. The active structure 130 has an upper surface 130S1 and a lower surface 130S2. The upper surface 130S1 is closer to the second semiconductor structure 150 than the lower surface 130S2, in other words, the lower surface 130S2 is closer to the first semiconductor structure 110 than the upper surface 130S1.

In an embodiment, the semiconductor stack 1E may be formed on a growth substrate (not shown) by epitaxial growth. The growth substrate may include a sapphire (Al₂O₃) substrate, a gallium nitride (GaN) substrate, a silicon carbide (SiC) substrate or an aluminum nitride (AlN) substrate. In an embodiment, the growth substrate may be a patterned substrate, that is, a surface of the growth substrate which the semiconductor stack 1E is formed on may have a patterned structure.

In any embodiment of the present application, the way for processing epitaxial growth may include metal organic chemical vapor deposition (MOCVD), hydride vapor deposition (HVPE), molecular beam epitaxy (MBE), physical vapor deposition (PVD) or liquid-phase epitaxy (LPE) method, but is not limited thereto. MOCVD epitaxial growth method will be used for representative description in the following embodiments.

The semiconductor stack 1E includes a semiconductor light-emitting stack constituting a light-emitting element such as a light-emitting diode or a laser. By changing the physical and chemical composition of one or more layers, such as the active structure 130, of the semiconductor stack 1E, the wavelength of the emitted light thereof can be adjusted. The first semiconductor structure 110, the active structure 130 and the second semiconductor structure 150 may include the same series of III-V semiconductor materials, such as InGaN series materials, AlGaN series materials or AlInGaN series materials. When the material of the active structure 130 includes InGaN series materials, a blue light with a wavelength between 400 nm and 490 nm, a cyan light (cyan) with a wavelength between 490 nm and 530 nm, or a green light with a wavelength between 530 nm and between 570 nm can be emitted from the active structure 130. When the material of the active structure 130 includes AlGaN series or AlInGaN series materials, an ultraviolet light with a wavelength between 250 nm and 400 nm can be emitted from the active structure 130. In an embodiment, the active structure 130 may include a single heterostructure, a double heterostructure, or a multiple quantum well. In an embodiment, the materials of the active structure 130 may be i-type, p-type or n-type semiconductors.

In an embodiment, before forming the semiconductor stack 1E, a buffer structure (not shown) can be formed on the growth substrate. The buffer structure can reduce the dislocation caused by the lattice mismatch between the growth substrate and the semiconductor stack 1E to improve the epitaxy quality. The buffer structure may contain a single layer or multiple layers. In an embodiment, the buffer structure includes AlᵢGa₍₁₋ᵢ₎N, wherein 0≤i≤1. In an embodiment, the material of the buffer structure includes GaN. In another embodiment, the material of the buffer structure includes AlN. The way for forming the buffer structure can be MOCVD, MBE, HVPE or PVD. The PVD includes sputtering or electron beam evaporation. When the buffer structure includes multiple sublayers (not shown), the sublayers include the same material or different materials. In an embodiment, the buffer structure includes two sublayers, wherein the first sublayer is grown by sputtering, and the second sublayer is grown by MOCVD. In an embodiment, the buffer structure includes a third sublayer. The third sublayer is grown by MOCVD, and a growth temperature of the second sublayer may be higher or lower than a growth temperature of the third sublayer. In an embodiment, the first, second and third sub-layers include the same material, such as AlN, or a combination of different materials, such as AlN, GaN and AlGaN. In another embodiments, PVD-AlN may be the buffer layer, and a target used to form PVD-AlN is composed of aluminum nitride, or using an aluminum-composed target in a nitrogen-source environment to reactively form aluminum nitride. In an embodiment, the buffer structure may be undoped, including not intentionally doped. In another embodiment, the buffer structure may include a dopant such as silicon, carbon, hydrogen, oxygen or a combination thereof, and the concentration of this dopant in the buffer structure is not less than 1×10¹⁷/cm³.

In an embodiment, in order to reduce lattice mismatch between the first semiconductor structure 110 and the active structure 130 that can cause the epitaxial defect, the first semiconductor structure 110 may include a stress-releasing region (not shown) adjacent the active structure 130. The stress-releasing region can be a superlattice structure alternately stacked by two semiconductor layers composed of different materials. The two semiconductor layers are, for example, indium gallium nitride (InGaN) layer and gallium nitride (GaN) layer, or aluminum gallium nitride layer (AlGaN) layer and gallium nitride (GaN) layer. The stress-releasing region can also be formed by a semiconductor stack including multiple layers having the same effect and different composed materials, such as a graduated multilayer structure composed by Group III elements.

In an embodiment, the second semiconductor structure 150 may include an electron blocking region (not shown) adjacent the active structure 130. The electron blocking region can block the electrons injected from the first semiconductor structure 110 into the active structure 130 from entering the second semiconductor structure 150 without having been recombined with holes in the wells of the active structure 130. The electron blocking region has a higher energy bandgap than that of the barriers in the active structure 130. The electron blocking region may include a single layer, a plurality of sublayers, or a plurality of alternating first sublayers and second sublayers. In an embodiment, a plurality of alternating first sublayers and second sublayers form a superlattice structure. In an embodiment, the electron blocking region includes the second conductivity-type dopant, and the dopant concentration is greater than 1×10¹⁷/cm³ and/or not greater than 1×10²¹/cm³.

In an embodiment, the second semiconductor structure 150 may include a contact region (not shown), and the material of the contact region may include Al_{g}Ga_{(1-g)}N, wherein 0<g≤1. In an embodiment, the dopant concentration of the second conductivity-type dopant in the contact region is greater than 5×10¹⁸/cm³, for example, 1×10¹⁹/cm³. In an embodiment, the contact region may further include the first conductivity-type dopant, such as Si, which may form an ohmic contact with the electrode of the light-emitting device. In an embodiment, the dopant concentration of the second conductivity-type dopant is greater than that of the first conductivity-type dopant. In an embodiment, the dopant concentration of the second conductivity-type dopant is less than that of the first conductivity-type dopant. In some embodiments, the contact region may include a multilayer structure, such as a superlattice structure. By adjusting the dopant concentration or the gradience of composed materials of the multilayer structure, the epitaxial quality of the contact region can be improved. In an embodiment, the second semiconductor structure 150 may include one or more layers other than the electron blocking region and the contact region. For example, a diffusion prevention layer (not shown) may be disposed between the electronic blocking region and the active structure 130. The diffusion prevention layer is used to prevent the second conductivity-type dopant of second semiconductor structure 150 or of the electron blocking region from diffusing into the active structure 130. The deterioration of epitaxial quality or efficiency in the active structure 130 can be avoided accordingly.

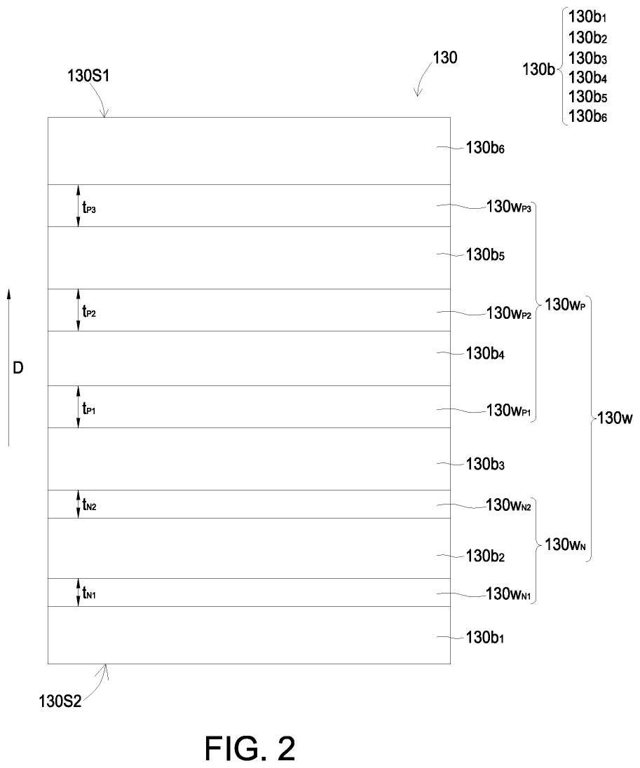

FIG. 2 is an enlarged view of a schematic cross-section of the active structure 130 of the semiconductor stack 1E in accordance with an embodiment of the present application. The active structure 130 includes a multiple quantum well structure alternately stacked by a plurality of barriers 130b and wells 130w. In an embodiment, the plurality of wells 130w includes a first well set 130w_{N} and a second well set 130w_{P}. The first well set 130w_{N} is disposed on the first semiconductor structure 110. The second well set 130w_{P} is disposed between the first well set 130w_{N} and the second semiconductor structure 150. In an embodiment, the first well set 130w_{N} is closer to the lower surface 130_{S2} than the second well set 130w_{P}, and the second well set 130w_{P} is closer to the upper surface 130_{S1} than the first well set 130w_{N}. In an embodiment, the first well set 130w_{N} may include one or multiple first wells 130i_{Ni}. The second well set 130w_{P} may include one or multiple second wells 130w_{Pi}, i=1, 2 . . . n; i′=1, 2 . . . n′). The plurality of barriers 130b may include multiple barriers 130_{bj} (j=1, 2 . . . m). Wherein n, n′ and m are positive integers, and the energy bandgap of the plurality of barriers 130b are greater than that the plurality of wells 130w. In other words, a bandgap of the multiple barriers 130bj are greater than that of the first well set 130w_{N} and the second well set 130w_{P}, thereby the carriers may be confined in the wells for recombination. In an embodiment, the plurality of wells 130w and the plurality of barriers 130b respectively include Group III-V semiconductor materials including a Group III element. In an embodiment, each of the plurality of barriers 130b includes AlGaN. In an embodiment, each of the plurality of barriers 130b includes GaN. In an embodiment, the plurality of barriers 130b may or may not include dopants, and the dopants may be n-type dopants. In an embodiment, the n-type dopant includes a Group IV element, such as silicon. In an embodiment, each barrier 130b is thicker than each well 130w. In an embodiment, the thickness of each barrier 130b is between 30 Å and 300 Å.

Referring to FIG, 2, in an embodiment, an active structure 130 taken as an example for explanation may include two first wells 130w_{N1}, 130w_{N2}, three second wells 130w_{P1}, 130w_{P2}, 130w_{P3}, and six barriers 130_{b1}, 130_{b2}, 130_{b3}, 130_{b4}, 130_{b5}, 130_{b6}. The barriers 130_{b1}, 130_{b2}, 130_{b3}, 130_{b4}, 130_{b5}, and 130_{b6} are arranged alternately with the first wells 130w_{N1}, 130w_{N2} and the second wells 130w_{P1}, 130w_{P2}, and 130w_{P3} respectively. As shown in FIG. 2, the barrier 130_{b1} serves as a starting layer for the active structure 130 locating on the first semiconductor structure 110, and the lower surface of the barrier 130_{b1} is the lower surface 130_{S2} of the active structure 130. The first well 130w_{N1} is located on the barrier 130_{b1}. Then, the barriers 130_{b2}, 130_{b3}, 130_{b4}, 130_{b5}, 130_{b6}, the first well 130w_{N2} and the second wells 130w_{P1}, 130w_{P2}, 130w_{P3} are alternately arranged in sequence along a direction D (i.e., the epitaxial growth direction) from the first semiconductor structure 110 to the second semiconductor structures 150, and the barrier 130_{b6} serves as an ending layer of the active structure 130, and the upper surface of the barrier 130_{b6} is the upper surface 130_{S1} of the active structure 130. In other embodiments, the number of the first well 130w_{Ni} may be greater than, equal to, or less than the number of the second well 130w_{Pi′}, that is, n may be greater than, equal to, or less than n′. In an embodiment, the active structure 130 can have the first well 130w_{Ni} or the barrier 130_{bj} as the starting layer, and have the second well 130w_{Pi′} or the barrier 130_{bj} as the ending layer. That is, the total number of layers n+n′ of the wells 130w may be greater than, equal to, or less than the total number of layers m of the barrier 130b, but is not limited thereto.

In an embodiment, each of the wells 130w has a thickness t, wherein the thickness t of one or multiple wells 130w closer to the second semiconductor structure 150 is different from the thickness t of one or multiple wells 130w closer to the first semiconductor structure 110. In an embodiment, the thickness t of the one or multiple wells 130w closer to the second semiconductor structure 150 is greater than the thickness t of the one or multiple wells 130w closer to the first semiconductor structure 110. In an embodiment, referring to FIG. 2, one or multiple first wells 130w_{Ni} respectively have first thicknesses t_{Ni}, and one or multiple second wells 130w_{Pi′} respectively have second thicknesses t_{Pi′}. In an embodiment, the first thicknesses t_{Ni} and the second thicknesses t_{Pi′} are different. In an embodiment, the second thicknesses t_{Pi′} are greater than the first thicknesses t_{Ni}. Taking the embodiment of FIG. 2 as an example, the first wells 130w_{N1} and 130w_{N2} have first thicknesses t_{N1} and t_{N2} respectively, and the second wells 130w_{P1}, 130w_{P2} and 130w_{P3} have second thicknesses t_{P1}, t_{P2} and t_{P3} respectively. Any one of the second thicknesses t_{P1}, t_{P2}, and t_{P3} is greater than any one of the first thicknesses t_{N1} and t_{N2}. In an embodiment, the thicknesses t_{N1} and t_{N2} of each of the first wells 130w_{N1} and 130w_{N2} are substantially equal. In an embodiment, the thicknesses t_{P1}, t_{P2}, and t_{P3} of each of the second wells 130w_{P1}, 130w_{P2}, and 130w_{P3} are substantially equal. In an embodiment, t_{P1}=t_{P2}=t_{P3}>t_{N1}=t_{N2}. In an embodiment, the materials of the first well 130w_{Ni} and the second well 130w_{Pi′} may be the same or different. In an embodiment, the material composition of the first well 130w_{Ni} may be the same as the second well 130w_{Pi′}, which includes AlₓIn_{y}Ga_{1-x-y}N, 0≤x≤1, 0≤y≤1, 0≤1−x−y<1. For example, using a transmission electron microscope and an X-ray energy dispersion analyzer, the depth positions of each layer of the first well 130w_{Ni} and the second well 130w_{Pi′} can be analyzed and measured to determine that the material composition of each layer is substantially the same.

The movement rate of electrons in a semiconductor layer is greater than that of holes. Therefore, when carriers are injected into the active structure 130, electrons may mainly accumulate in the wells close to a p-type semiconductor layer, and electrons may be recombined with holes injected from the p-type semiconductor layer in one or more wells close to the p-type semiconductor layer. The wells farther away from the p-type semiconductor layer have less injected holes, accordingly the number of electron-hole recombination may decrease. In other words, in the active structure 130, the main recombination location of electrons and holes may be in the active structure closer to the p-type semiconductor layer. Taking this embodiment as an example, the first semiconductor structure 110 includes an n-type semiconductor layer, and the second semiconductor structure 150 includes a p-type semiconductor layer. Electrons and holes are injected into the active structure 130 from the first semiconductor structure 110 and the second semiconductor structure 150 respectively. Therefore, the main recombination location may be in a region of the active structure 130 close to the second semiconductor structure 150. Such uneven carrier injection phenomenon may cause the light-emitting intensity of the wells close to the second semiconductor structure 150 to be greater than the light-emitting intensity of the wells close to the first semiconductor structure 110. In another embodiment, when the active structure 130 emits light with a shorter wavelength, such as UV light, the main recombination position may be in a region of the active structure 130 close to the second semiconductor structure 150, by adjusting the thicknesses of the wells of the active structure 130, for example, decreasing the thicknesses of the wells close to the first semiconductor structure 110 (n-type semiconductor layer), increasing the thickness of the wells close to the second semiconductor structure 150 (p-type semiconductor layer), or both increasing the thicknesses of the wells close to the second semiconductor structure 150 and decreasing the thicknesses of the wells close to the first semiconductor structure 110. Accordingly, the thicknesses of the wells close to the second semiconductor structure 150 are greater than the thicknesses of the wells close to the first semiconductor structure 110. Since the wells close to the first semiconductor structure 110 emit less light than the wells close to the second semiconductor structure 150, if the wells close to the second semiconductor structure 150 have greater thicknesses than the wells close to the first semiconductor structure 110, the radiation recombination in the wells close to the second semiconductor structure 150 may occupy more percentage of the entire radiation recombination in all wells, thereby improving the light-emitting intensity and efficiency of the semiconductor stack 1E. In an embodiment, where the thicknesses of the wells close to the second semiconductor structure 150 are greater than the thicknesses of the wells close to the first semiconductor structure 110 may suppress the light-absorption of the wells close to the first semiconductor structure 110. For example, the thicknesses of the wells close to the first semiconductor structure 110 may be reduced, thereby improving the light-emitting intensity and efficiency of the semiconductor stack 1E. In an embodiment, all wells of the active structure 130 can be further designed to have the same material composition, so as to improve the light-emitting intensity and efficiency and make a domain light-emitting wavelength of each well consistent at the same time. Since the domain light-emitting wavelength of each well is substantially the same, the half-maximum width of the light spectrum can be narrowed, thereby the light emitted by the active structure 130 can be purified.

In an embodiment, the number of the second wells 130w_{Pi′} is greater than the number of the first wells 130w_{Ni}, that is, n′ is greater than n. In an embodiment, the first thickness t_{Ni} and the second thickness t_{Pi′} may be between 10 Å and 200 Å. In an embodiment, the first thickness t_{Ni} may be between 10 Å and 80 Å. In an embodiment, the second thickness t_{Pi′} may be between 30 Å and 100 Å. In an embodiment, in the active structure 130 by designing a ratio range of thickness difference (tₚᵢ−t_{Ni})/t_{Pi′} between 1% and 70%. In another embodiment, the ratio range may be between 1% to 10%. In another embodiment, the ratio range may be between 3% to 20%. By designing the number of wells close to the second semiconductor structure 150 and having greater thicknesses to be greater than the number of wells close to the first semiconductor structure 110 and having less thickness, the above effect can be further enhanced. In an embodiment, in the active structure 130 by designing a ratio range of (tₚᵢ−t_{Ni})/t_{Pi′} between 1% and 70%, the half-maximum width of the spectrum can be narrowed to purify the light emitted by the active structure 130, and the light-emitting intensity and efficiency can be improved. In an embodiment, when the active structure 130 emits light with a domain wavelength between 420 nm and 460 nm, and the ratio range of thickness difference is between 1% and 10%, the above effect can be more significant. In an embodiment, when the active structure 130 emits light with a domain wavelength between 350 nm and 400 nm, the ratio range of thickness difference is between 3% and 20%, and the above effect can be more significant.

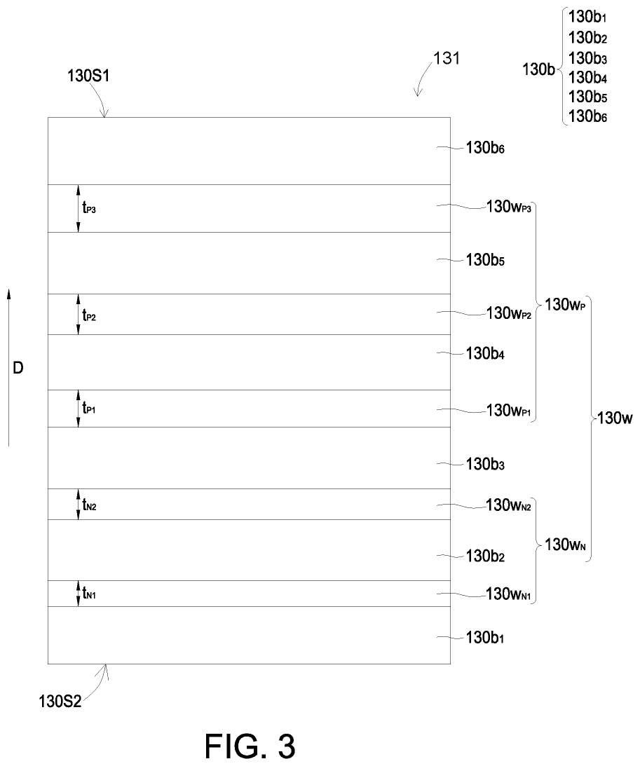

FIG. 3 is a schematic enlarged cross-sectional view of an active structure 131 of the semiconductor stack 1E in accordance with an embodiment of the present application. The process and structure of the active structure 131 are similar to those of the active structure 130. Similar processes and structures can be found in the description and figures of the active structure 130. The following paragraphs describe the differences without repeating similar processes and structures. As shown in FIG. 3, a plurality of wells 130w includes a first well set 130w_{N} and a second well set 130w_{P}. The first well set 130w_{N} is disposed on the first semiconductor structure 110, and the second well set 130w_{P} is disposed between the first well set 130w_{N} and the second semiconductor structure 150. In other words, the first well set 130w_{N} is closer to the lower surface 130S2 than the second well set 130w_{P}, and the second well set 130w_{P} is closer to the upper surface 130S1 than the first well set 130w_{N}. The difference between the active structure 130 and the active structure 131 is that the first thicknesses tri of the first wells 130w_{Ni} of the first well set 130w_{N} gradually increase along a direction D from the first semiconductor structure 110 toward the second semiconductor structure 150. In an embodiment, the second thicknesses t_{Pi} of the second wells 130w_{Pi′} of the second well 130w_{P} gradually increase along the direction D. In an embodiment, the first thicknesses t_{Ni} of the first wells 130w_{Ni} of the first well set 130w_{N} and the second thicknesses t_{Pi} of the second wells 130w_{Pi′} of the second well set 130w_{P} gradually increase along the direction D. In an embodiment, a thickness difference Δt1 may be between adjacent wells of the first wells 130w_{Ni}, and a thickness difference Δt2 may be between adjacent wells of the second wells 130w_{Pi′}, wherein Δt1 can be greater than, less than, or equal to Δt2. A thickness difference between a first well 130w_{N2} of the first well set 130w_{N} and a second well 130w_{P1} adjacent to the first well 130w_{N2} of the second well set 130w_{P} set may be equal or not equal to At1 or At2. In an embodiment, taking the embodiment of FIG. 3 as an example, the first wells 130w_{N1} and 130w_{N2} have the first thicknesses t_{N1} and t_{N2} respectively, and the second wells 130w_{P1}, 130w_{P2} and 130w_{P3} have the second thicknesses t_{P1}, t_{P2} and t_{P3} respectively, wherein t_{P3}>t_{P2}>t_{P1}>t_{N2}>t_{N1}, the thickness differences Δt1 and Δt2 between each well can be the same or different.

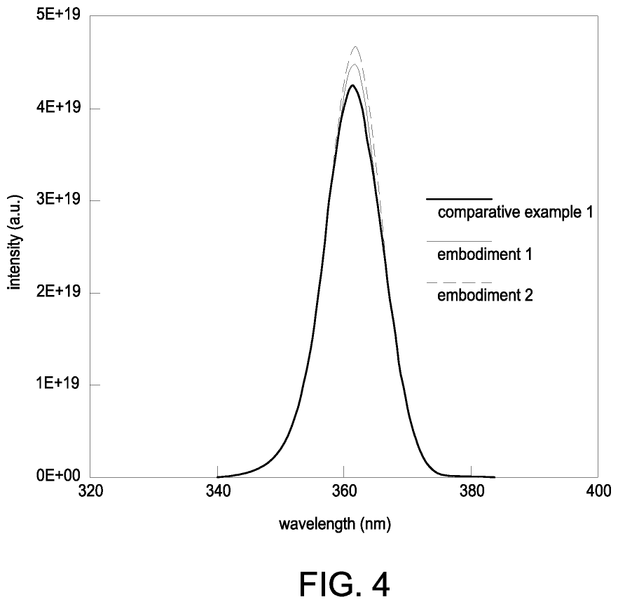

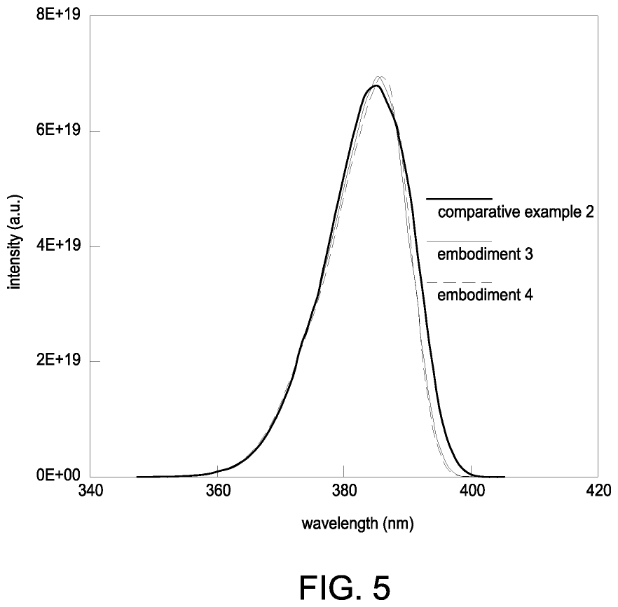

FIGS. 4 and 5 respectively show simulation curves of light-emitting intensity of a semiconductor stack in accordance with an embodiment of the present application and a semiconductor stack in accordance with a comparative example. The semiconductor stack 1E of FIG. 1 is used for simulating the comparation between the comparative example and the embodiments of present application. Referring to FIG. 4, the difference between a comparative example 1 and the embodiments 1 and 2 is disclosed. In an active structure of the comparative example 1, a thickness of each layer of the first well set 130w_{N} and a thickness of each layer of the second well set 130w_{P} are the same, however, in an active structure of the embodiment 1, the first wells of the first well set 130w_{N} have the same thickness, the second wells of the second well set 130w_{P} have the same thickness, and each second well of the second well set 130w_{P} is thicker than each first well of the first well set 130w_{N}, that is, the active structure of embodiments 1 and 2 may be similar to the active structure 130 of FIG. 2. The thickness difference between a second well of the second well set 130w_{P} and a first well of the first well set 130w_{N} may be about 18% of the thickness of the second well set 130w_{P}. In the active structure of the embodiment 2, the thicknesses of the first wells of the first well set 130w_{N} increase with a fixed difference Δt1 along the direction D from the first semiconductor structure 110 toward the second semiconductor structure 150. The thicknesses of the second wells of the second well set 130w_{P} increase with a fixed difference Δt2 along the direction D, that is, the active structure thereof is similar to the active structure 131 of FIG. 3, Δt1 may be equal to Δt2, and the thickness of each second well of the second well set 130w_{P} may be greater than each first well of the first well set 130w_{N}. Since the materials of the wells and the barriers in the active structure of the comparative example 1 are the same with those of the embodiment 1 and embodiment 2, the theoretical peak wavelength of the emitted light of the comparative example 1, embodiment 1, and embodiment 2 are the same, such as approximately between 350 nm and 370 nm. As shown in FIG. 4, when the material compositions of the wells of the comparative example 1, embodiment 1, and embodiment 2 are the same, in the simulation curve of wavelength relative to the light-emitting intensity obtained by adjusting the thicknesses of the wells, the peak wavelength values of emitted light of the comparative example 1, embodiment 1, and embodiment 2 are substantially the same. Compared with the comparative example 1, embodiment 1 and embodiment 2 each has a narrower half-maximum width and greater light-emitting intensity. Further, embodiment 2 has a narrower half-width and greater light-emitting intensity than those of the embodiment 1.

Referring to FIG. 5, the difference between a comparative example 2 and the embodiments 3 and 4 is disclosed. In an active structure of the comparative example 2, the thicknesses of the first wells of the first well set 130w_{N} and the thicknesses of the second wells of the second well set 130w_{P} are all the same for simulation. In an active structure of embodiment 3, the thicknesses of the layers of the first well set 130w_{N} are the same, and the thicknesses of the second wells of the second well set 130w_{P} are the same, and the thickness of each second well of the second well set 130w_{P} is greater than the thickness of each first well of the first well set 130w_{N}, that is, the active structure thereof is similar to the active structure 130 of FIG. 2. A thickness difference between one second well of the second well set 130w_{P} and one first well of the first well 130w_{N} is about 18% of the thickness of one second well of the second well set 130w_{P}. In the active structure of the embodiment 4, the thicknesses of the first wells of the first well set 130w_{N} increase with a fixed difference Δt1 along the direction D from the first semiconductor structure 110 toward the second semiconductor structure 150. The thicknesses of the second wells of the second well set 130w_{P} increase with the fixed difference Δt1 along the direction D, that is, the active structure thereof is similar to the active structure 131 of FIG. 3, Δt1 is equal to Δt2, and the thickness of each second well of the second well set 130w_{P} is greater than the thickness of each first well of the first well set 130w_{N}. Since the materials of the wells and the barriers in the active structure of the comparative example 2 are the same with those of the embodiment 3 and embodiment 4, the theoretical peak wavelength of the emitted light of the comparative example 2, embodiment 2, and embodiment 4 are the same, such as approximately between 370 nm and 400 nm. As shown in FIG. 5, when the material compositions of the wells of the comparative example 2, embodiment 3, and embodiment 4 are the same, in the simulation curve of wavelength relative to the light-emitting intensity obtained by adjusting the thicknesses of the wells, the peak wavelength values of emitted light of the comparative example 2, embodiment 3, and embodiment 4 are substantially the same. Compared with the comparative example 2, embodiment 3 and embodiment 4 each has a narrower half-maximum width and greater light-emitting intensity.

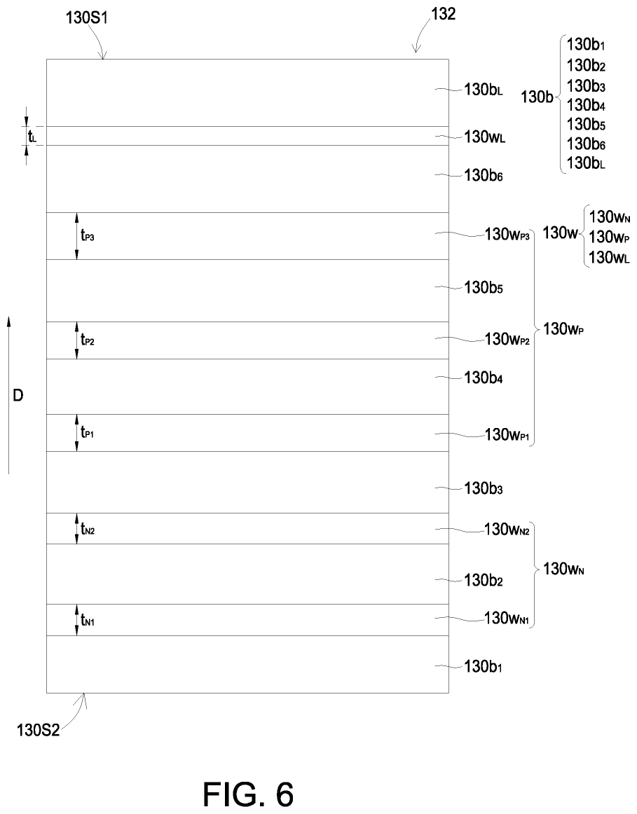

FIG. 6 is a schematic enlarged cross-sectional view of an active structure 132 of the semiconductor stack 1E in accordance with an embodiment of the present application. The process and structure of the active structure 132 are similar to those of the active structure 130 and the active structure 131. Similar processes and structures can be found in the description and figures of the active structure 130 and the active structure 131. The following paragraphs describe the differences without repeating similar processes and structures. As shown in FIG. 6, a plurality of wells 130w includes a first well set 130w_{N} and a second well set 130w_{P}. The first well set 130w_{N} is disposed on the first semiconductor structure 110, and the second well set 130w_{P} is located between the first well set 130w_{N} and the second semiconductor structure 150. In other words, the first well set 130w_{N} is closer to the lower surface 130_{S2} than the second well set 130w_{P}, and the second well set 130w_{P} is closer to the upper surface 130_{S1} than the first well set 130w_{N}. The difference between the active structure 132 and the active structures 130 or 131 is that the active structure 132 further includes a last well 130w_{L} located between the second well set 130w_{P} and the second semiconductor structure 150 and a last barrier 130b_{L} located between the last well 130w_{L} and the second semiconductor structure 150. The last well 130w_{L} has a third thickness t_{L}, wherein the third thickness t_{L} is less than the second thickness t_{Pi} of any second well 130w_{Pi′} of the second well set 130w_{P}. In an embodiment, the third thickness t_{L} is less than the first thickness t_{Ni} of any first well 130w_{Ni} of the first well set 130w_{N}, and the material of the last well 130w_{L} includes AlₓIn_{y}Ga_{1-x-y}N, 0≤x≤1, 0≤y≤1, 0≤1−x−y<1. In an embodiment, the third thickness ty is less than the first thickness t_{Ni} of the first well 130w_{Ni} of the first well set 130w_{N} and the second thickness t_{Pi} of the second well 130w_{Pi′} of the second well set 130w_{P}. The upper surface of the last barrier 130b_{L} is the upper surface 130S1 of the active structure 132. In an embodiment, the materials of the first well 130w_{Ni}, the second well 130w_{Pi′} and the last well 130w_{L} are the same. In an embodiment, along the direction D from the first semiconductor structure 110 toward the second semiconductor structure 150, one or multiple consecutive first wells 130w_{Ni} are defined as a set, and one or more consecutive second wells 130w_{Pi′} are defined as a set. The thicknesses of the wells in the same set are the same, and there is a thickness difference Δt3 between adjacent sets. The thicknesses of the wells of the multiple sets increase with a fixed difference Δt3 along the direction D. As shown in FIG. 6, in an embodiment, the relationship between the thicknesses of the two first wells 130w_{N1} and 130w_{N2} and the three second wells 130w_{P1}, 130w_{P2} and 130w_{P3} is t_{P3}>t_{P2}=t_{P1}>t_{N2}=t_{N1}. In an embodiment, the thickness relationship of the two first wells 130w_{N1} and 130w_{N2}, the three second wells 130w_{P1}, 130w_{P2}, 130w_{P3}, and the last well 130w_{L} is t_{P3}>t_{P2}=t_{P1}>t_{N2}=t_{N1}>t_{L}. In an embodiment, the thickness relationship of the two first wells 130w_{N1} and 130w_{N2}, the three second wells 130w_{P1}, 130w_{P2}, 130w_{P3}, and the last well 130w_{L} is t_{P3}>t_{P2}>t_{L}=t_{P1}>t_{N2}=t_{N1}. In an embodiment, the thickness relationship of the two first wells 130w_{N1} and 130w_{N2}, the three second wells 130w_{P1}, 130w_{P2}, 130_{P}w₃, and the last well 130w_{L} is t_{P3}>t_{P2}=t_{P1}>t_{N2}>t_{L}=t_{N1}. In an embodiment, the active structure 132 emits a light with a domain wavelength between 420 nm and 460 nm, and the thickness of each well is thinner than those in the above embodiments. In an embodiment, the thickness of each well is about less than 50 Å. By providing such thickness-relationship adjustment to the wells, the polarization effect caused by the lattice mismatch between the second semiconductor structure 150 and a well adjacent the second semiconductor structure 150 of the active structure 132 can be eased, thereby reducing the impact of the polarization effect on the light-emitting efficiency. For example, the material of the second semiconductor structure 150 forms a high-energy band layer, and the material of the well forms a low-energy band layer. A tensile stress may occur between the low-energy band layer and the high-energy band layer to cause a polarization effect, and resulting in decreasing light-emitting efficiency. Therefore, by designing the active structure 132 to include a thinner last well 130w_{L}, the polarization effect can be eased, thereby reducing the impact of the polarization effect on the light-emitting efficiency.

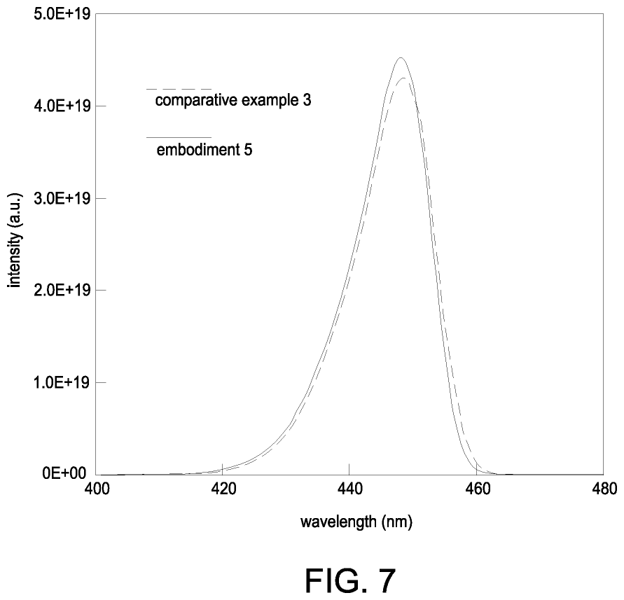

FIG. 7 shows a simulation curve of light-emitting intensity of a semiconductor stack in accordance with an embodiment of the present application and a semiconductor stack in accordance with a comparative example. The semiconductor stack 1E of FIG. 1 is used for simulating the comparation between the comparative example and the embodiments of present application. Referring to FIG. 7, the difference between a comparative example 3 and an embodiment 5 is disclosed. In an active structure of the comparative example 3, the first well set 130w_{N}, the second well set 130w_{P} and the last well 130w_{L} have the same thickness. In an active structure of embodiment 5, one or multiple consecutive first wells 130w_{Ni} are defined as a set, and one or more consecutive second wells 130w_{Pi′} are defined as a set along the direction D from the first semiconductor structure 110 toward the second semiconductor structure 150. The thicknesses of the wells in the same set are the same. There is a thickness difference Δt3 between wells respectively located in adjacent sets. The thicknesses of the wells in the multiple sets are increased with a fixed thickness difference Δt3 between adjacent sets along the direction D. In other words, along the direction D, the thicknesses of the wells in a set are the fixed thickness difference Δt3 greater than those in a prior set. Similar to the active structure 132 of FIG. 6, the thickness of the last well 130w_{L} is less than the thicknesses of the first wells 130w_{Ni} and the second wells 130w_{Pi′}. Since the materials of the wells and the barriers in the active structure of the comparative example 3 are the same with those of the embodiment 5, the theoretical peak wavelength of the emitted light of the comparative example 3 and embodiment 5 are the same, for example, approximately between 420 nm and 460 nm. As shown in FIG. 7, when the material compositions of the wells of the comparative example 3 and the embodiment 5 are the same, in the simulation curve of wavelength relative to the light-emitting intensity obtained by adjusting the thicknesses of the wells, the peak wavelength values of emitted light of the comparative example 3 and the embodiment 5 are substantially the same. Compared with the comparative example 3, embodiment 5 has a narrower half-maximum width and greater light-emitting intensity. A polarization effect caused by a lattice mismatch between the second semiconductor structure 150 and the active structure 132 may be eased by adjusting an energy gap of a well adjacent to the second semiconductor structure 150. Therefore, some negative impacts on light-emitting efficiency caused by the polarization effect may be reduced, and some effects such as increasing light purity and intensity can be achieved. In a modified embodiment, the well of the active structure 132 includes InGaN series materials, for example, emitting light with a domain wavelength between 420 nm and 460 nm. The energy gap of the last well 130w_{L} adjacent to the second semiconductor structure 150 can be adjusted to be between the energy gaps of the second semiconductor structure 150 and other wells. The overall indium composition of the last well 130w_{L} may be reduced to increase the energy gap of the last well 130w_{L}. For example, the indium composition of the last well 130w_{L} may be reduced or the thickness of the last well 130w_{L} may be reduced. In order to reduce the indium composition of the last well 130w_{L}, the growth temperature for epitaxially growing the last well 130w_{L} can be increased, or the flow rate of indium source during epitaxially growing the last well 130w_{L} can be reduced. The difference between the modified embodiment and embodiment 5 is that the indium composition of the last well 130w_{L} of the modified embodiment is different from the indium composition of the first well set 130w_{N} and/or the second well set 130w_{P}. For example, the indium composition of the last well 130w_{L} of the modified embodiment may be less than the indium composition of the first well set 130w_{N} and/or the second well set 130w_{P}. In specific, the first wells 130w_{Ni} and the second wells 130w_{Pi′} may have the same indium composition, while the last well 130w_{L} has a lower indium composition than the first wells 130w_{Ni} and the second wells 130w_{Pi}. In another modified embodiment, the last well 130w_{L} may be omitted, and the indium composition of a second well 130w_{Pi′} closest to the second semiconductor structure 150 may be lower than those of other wells. In another modified embodiment, the thickness and indium composition of the last well 130w_{L} can be reduced at the same time, or the thickness and the indium composition of the well closest to the second semiconductor structure 150 of the second well layer 130w_{Pi} can be reduced at the same time. Compared with the comparative examples, the semiconductor stack of each modified embodiment may emit a light having a narrower half-maximum width and greater light-emitting intensity.

In an embodiment, the semiconductor stack 1E of any of the embodiments may include one or multiple V-shaped recesses (not shown), and the one V-shaped recess or each of the multiple V-shaped recesses has a bottom and an inclined surface. The bottom is closer to the first semiconductor structure 110 than the inclined surface, and the inclined surface is closer to the second semiconductor structure 150 than the bottom. In an embodiment, the active structure 130 emits a light with a domain wavelength between 320 nm and 400 nm, and the bottom of the one V-shaped recess or each of the multiple V-shaped recesses may be located in the active structure 130 and/or in the stress-releasing region. In an embodiment, the active structure 130 emits a light with a domain wavelength between 380 nm and 460 nm, and the bottom of the one V-shaped recess or each of the multiple V-shaped recesses may be located in the first semiconductor structure 110 (stress-releasing region). Since each V-shaped recess has a continuous inclined surface, the thicknesses of the barriers and the wells located on this inclined surface is thinner than the thickness on the plane outside the V-shaped recess. Taking the growth substrate being a sapphire substrate as an example, the plane for epitaxially growing the semiconductor stack 1E of the growth substrate is a polar plane (C plane), and the inclined surface of the V-shaped recess is a semi-polar plane, which makes it easier for the holes to tunnel through the barriers and the wells, therefore the injected holes can be increased, and the light-emitting efficiency can be improved.

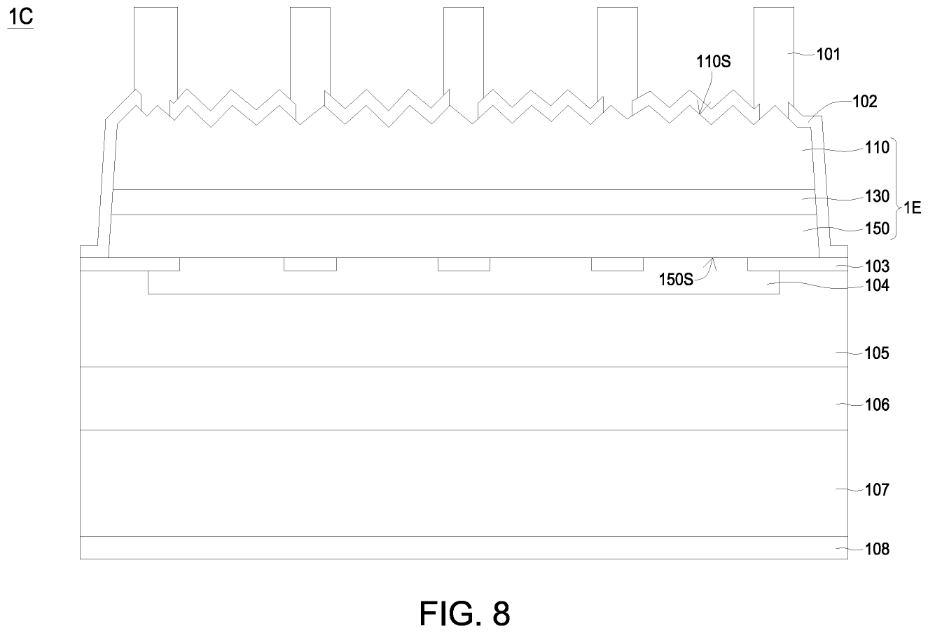

FIG. 8 shows a schematic cross-sectional view of a light-emitting element 1C in accordance with an embodiment of the present application. The light-emitting device 1C may include a conductive substrate 107, a second electrode structure 108 and the above-mentioned semiconductor stack 1E. The second electrode structure 108 and the semiconductor stack 1E are respectively disposed on opposite sides of the conductive substrate 107. In an embodiment, the semiconductor stack 1E originally grown on a growth substrate can be transferred and bonded to the conductive substrate 107, and then the growth substrate can be removed to expose the first semiconductor structure 110. The first semiconductor structure 110 has the first surface 110S, such as a light-emitting surface of the light-emitting element 1C. The second semiconductor structure 150 has a second surface 150S, such as a surface on a side opposite to the light-emitting surface of the light-emitting element 1C. In an embodiment, the first surface 110S of the first semiconductor structure 110 may include a roughing surface to improve the light-extraction efficiency.

The light-emitting device 1C may further include a first electrode structure 101, a patterned insulating layer 103, a metal reflective layer 104 and a metal barrier 105. The first electrode structure 101 may be disposed on the first surface 110S of the first semiconductor structure 110 to be in contact with the first semiconductor structure 110. The patterned insulating layer 103 and the metal reflective layer 104 can be disposed on the second surface 150S of the second semiconductor structure 150. The patterned insulating layer 103 can be disposed corresponding to a position of the first electrode structure 101. The width of the first electrode structure 101 may be smaller than that of the patterned insulating layer 103. The metal barrier 105 can be disposed on the patterned insulating layer 103 and the metal reflective layer 104. The metal barrier 105 and the semiconductor stack 1E are respectively disposed on opposite sides of the patterned insulating layer 103.

The light-emitting device 1C may further include a bonding layer 106 and a passivation layer 102. The bonding layer 106 is disposed between the metal barrier 105 and the conductive substrate 107. The passivation layer 102 may be disposed on the first surface 110S of the first semiconductor structure 110. The passivation layer 102 may cover a part of the first surface 110S of the first semiconductor structure 110 and the side surfaces of the semiconductor stack 1E. The passivation layer 102 can further cover the patterned insulating layer 103. The first electrode structure 101 may penetrate the passivation layer 102 and contact the first semiconductor structure 110. In an embodiment, the first electrode structure 101 is located on the passivation layer 102 and covers a part of the passivation layer 102. In an embodiment, the passivation layer 102 is not covered by the first electrode structure 101. In an embodiment, the passivation layer 102 may cover the side surfaces and a part of the upper surface of the first electrode structure 101. In an embodiment, the passivation layer 102 may conformally cover a rough surface of the first semiconductor structure 110, therefore the passivation layer 102 may have an upper surface including a concave-convex pattern. The metal barrier 105 may be able to prevent the materials of the bonding layer 106 from diffusing into the metal reflective layer 104 during the manufacturing process. The diffused materials of the bonding layer 106 may be reacted with the metal reflective layer 104 to form a compound or alloy affecting the reflectivity and conductivity of the metal reflective layer 104. The bonding layer 106 may connect the conductive substrate 107 and the semiconductor stack 1E.

In an embodiment, the conductive substrate 107 includes conductive materials or semiconductor materials, and the conductive substrate 107 may be transparent or opaque. The conductive substrate 107 may include a conductive material but is not limited to transparent conductive oxide (TCO), such as zinc oxide (ZnO), indium tin oxide (ITO), indium zinc oxide (IZO), gallium oxide (Ga₂O₃), lithium gallate (LiGaO₂), lithium aluminate (LiAlO₂) or magnesium aluminate (MgAl₂O₄), or may include conductive materials but not limited to metal materials such as aluminum (Al), copper (Cu), molybdenum (Mo), germanium (Ge) or tungsten (W) or alloys or stacks of the above materials; or may include but not limited to semiconductor materials, such as silicon (Si), silicon carbide (SiC), gallium arsenide (GaAs), gallium nitride (GaN), aluminum nitride (AN), gallium phosphide (GaP), gallium arsenide phosphorus (GaAsP), zinc selenide (ZnSe), zinc selenide (ZnSe), or indium phosphide (InP).

The first electrode structure 101 may include a conductive material. The first electrode structure 101 and the second electrode structure 108 may include the same or different materials. The first electrode structure 101 and the second electrode structure 108 may include metal materials or transparent conductive materials, for example, the metal materials may include but not limited to aluminum (Al), chromium (Cr), copper (Cu), tin (Sn), gold (Au), nickel (Ni), titanium (Ti), platinum (Pt), palladium (Pd), silver (Ag), lead (Pb), zinc (Zn), cadmium (Cd), antimony (Sb), cobalt (Co) or alloys of the above materials; transparent conductive materials may include but not limited to indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), aluminum gallium arsenide (AlGaAs), gallium nitride (GaN), gallium phosphide (GaP), gallium arsenide (GaAs), gallium arsenide phosphide (GaAsP), indium zinc oxide (IZO), diamond-like carbon (DLC) or graphene. In an embodiment, the first electrode structure 101 and the second electrode structure 108 respectively include single layer or multi-layer structures.

The material of the patterned insulating layer 103 may include insulating oxide, nitride, silicon oxide, titanium oxide, aluminum oxide, magnesium fluoride or silicon nitride. The material of the passivation layer 102 may include silicon nitride or silicon oxide. The material of the patterned insulating layer 103 may be different from that of the passivation layer 102. In an embodiment, the material of the patterned insulating layer 103 can be titanium dioxide (TiO₂), and the material of the passivation layer 102 can be silicon dioxide (SiO₂) or silicon nitride (SiNₓ or Si₃N₄). Because titanium dioxide has a better anti-etching characteristic, the patterned insulating layer 103 made of titanium dioxide can serve as an etching stop layer when etching the semiconductor stack 1E in the subsequent dicing process. Because silicon dioxide or silicon nitride have a better light-penetration characteristic, the passivation layer 102 made of silicon dioxide or silicon nitride is less likely to absorb light.

The metal reflective layer 104 may include metal material such as silver (Ag), gold (Au), aluminum (Al), titanium (Ti), chromium (Cr), copper (Cu), nickel (Ni), platinum (Pt), ruthenium (Ru), tungsten (W), rhodium (Rh) or an alloy or a stack of the above materials. In an embodiment, the metal reflective layer 104 may include a multi-layer structure (not shown), for example, the metal reflective layer 104 may include a multi-layer structure stacked by a first metal layer, a second metal layer and a third metal layer. The first metal layer, the second metal layer and the third metal layer are stacked in sequence. The first metal layer may include silver (Ag), the second metal layer may include titanium tungsten (TiW), and the third metal layer may include platinum (Pt). The metal reflective layer 104 may form an ohmic contact with the second semiconductor structure 150.

The metal barrier 105 may include metal materials such as aluminum (Al), chromium (Cr), platinum (Pt), titanium (Ti), tungsten (W), zinc (Zn), or an alloy or a stack including above materials. In an embodiment, when the metal barrier 105 is a metal stack, the metal barrier 105 is alternately stacked by two or more metal layers, such as Cr/Pt, Cr/Ti, Cr/TiW, Cr/W, Cr/Zn, Ti/Pt, Ti/W, Ti/TiW, Ti/Zn, Pt/TiW, Pt/W, Pt/Zn, TiW/W, TiW/Zn, or W/Zn.

The bonding layer 106 may include transparent conductive material or metal material. The transparent conductive material includes but are not limited to indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), Indium titanium oxide (ITiO), indium zinc oxide (IZO), indium gallium oxide (IGO), gallium aluminum zinc oxide (GAZO), graphene or a combination of the above materials. The metal material includes but are not limited to copper (Cu), aluminum (Al), tin (Sn), gold (Au), silver (Ag), lead (Pb), titanium (Ti), nickel (Ni), platinum (Pt), tungsten (W) or an alloy or a stack including above materials.

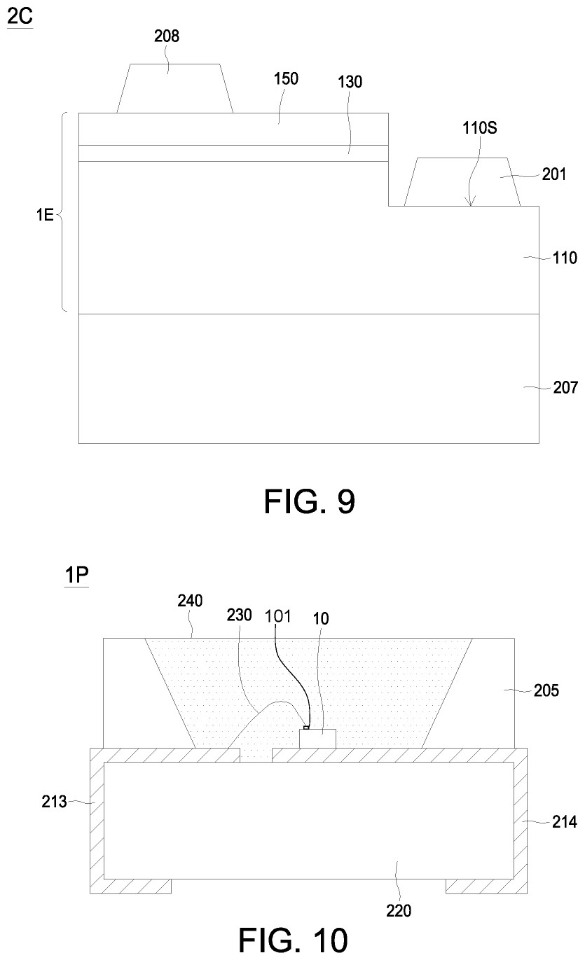

FIG. 9 shows a schematic cross-sectional view of a light-emitting element 2C in accordance with an embodiment of the present application. The light-emitting device 2C includes a carrier 207 and the above-mentioned semiconductor stack 1E on the carrier 207. The first semiconductor structure 110 has a first surface 110S not covered by the active structure 130 and the second semiconductor structure 150. A first electrode structure 201 is located on and electrically connected to the first surface 110S of the first semiconductor structure 110, and the second electrode structure 208 is located on and electrically connected to the second semiconductor structure 150. In an embodiment, a transparent conductive layer (not shown) may be disposed between the second electrode structure 208 and the second semiconductor structure 150. For a current blocking purpose, a patterned insulating layer may be disposed between the transparent conductive layer and the second semiconductor structure 150, and/or another patterned insulating layer may be disposed between the first electrode structure 201 and the first semiconductor structure 110. In an embodiment, the carrier 207 may be a growth substrate for growing the above-mentioned semiconductor stack 1E. In an embodiment, the carrier 207 may be a patterned substrate, that is, the carrier 207 has a patterned structure (not shown) on a surface where the semiconductor stack 1E is located. The light emitted from the semiconductor stack 1E may be refracted and/or reflected by the patterned structure of the carrier 207, thereby improving the brightness of the light-emitting element. In an embodiment, if the light-emitting element 2C is packaged in a flip-chip form, a reflective structure may be provided between the second electrode structure 208 and the second semiconductor structure 150, and the reflective structure may include a metal reflective structure or an insulating reflective structure. In an embodiment, the metal reflective structure may include a single metal layer or a stack formed by multiple metal layers. In an embodiment, the material of the metal reflective structure includes a metal material with high reflectivity to the light emitted by the active structure 130, such as silver (Ag), gold (Au), aluminum (Al), titanium (Ti), chromium (Cr), copper (Cu), nickel (Ni), platinum (Pt), ruthenium (Ru), tungsten (W), zinc (Zn), rhodium (Rh), or an alloy or a stack of above materials. In an embodiment, the insulating reflective structure may include a reflective structure composed of a material stack. The material stack is stacked according to different refractive index materials selection and thickness design. For example, the material stack is a distributed Bragg reflector (DBR) to provide reflectivity for light in a specific wavelength range emitted by the active structure 130. In an embodiment, the material stack is formed by dielectric materials, and the dielectric materials include silicon-containing material, such as silicon oxide (SiOₓ), silicon nitride (SiNₓ), or silicon oxynitride (SiOₓN_{y}); metal oxide, such as niobium oxide (Nb₂O₅), tantalum oxide (Ta₂O₅), hafnium oxide (HfO₂), titanium oxide (TiOₓ), or aluminum oxide (Al₂O₃); metal fluorides, such as magnesium fluoride (MgF₂).

The first electrode structure 201 and the second electrode structure 208 are for electrically connecting to an external power source or other electronic components and for conducting a current therebetween. Materials of the first electrode structure 201 and the second electrode structure 208 include metal materials. Metal materials include chromium (Cr), gold (Au), aluminum (Al), copper (Cu), silver (Ag), tin (Sn), nickel (Ni), rhodium (Rh), platinum (Pt), germanium gold nickel (GeAuNi), titanium (Ti), beryllium gold (BeAu), germanium gold (GeAu) or zinc gold (ZnAu). In some embodiments, each of the first electrode structure 201 and the second electrode structure 208 is a single layer, or a structure including multiple layers such as Ti/Au layer, Ti/Al layer, Ti/Pt/Au layer, Cr/Au layer, Cr/Pt/Au layer, Ni/Au layer, Ni/Pt/Au layer, Ti/Al/Ti/Au layer, Cr/Ti/Al/Au layer, Cr/Al/Ti/Au layer, Cr/Al/Ti/Pt layer or Cr/Al/Cr/Ni/Au layer, or a combination thereof. The material of the transparent conductive layer includes transparent conductive oxide or light-transmissive thin metal. The transparent conductive oxides are, for example, indium tin oxide (ITO), indium oxide (InO), tin oxide (SnO), cadmium tin oxide (CTO), antimony tin oxide (ATO), aluminum zinc oxide (AZO), zinc tin oxide (Zn₂SO₄, ZTO), gallium doped zinc oxide (GZO), tungsten doped indium oxide (IWO), zinc oxide (ZnO) or indium zinc oxide (IZO). Among them, chromium (Cr), gold (Au), aluminum (Al), copper (Cu), silver (Ag), tin (Sn), nickel (Ni), rhodium (Rh), platinum (Pt) or titanium (Ti) may be used to form a thin metal that can transmit light.

FIG. 10 shows a schematic cross-sectional view of a light-emitting package 1P in accordance with an embodiment of the present application. The light-emitting package IP in accordance with the embodiments may include an encapsulation wall 205, an encapsulation substrate 220, a first external electrode 213 and a second external electrode 214 installed on the encapsulation substrate 220, and a light-emitting element 10 installed in the encapsulation wall 205 and electrically connected to the first external electrode 213 and the second external electrode 214. The packaging material 240 may include phosphor surrounding the light-emitting element 10. The first external electrode 213 and the second external electrode 214 are electrically insulated from each other, and power can be provided to the light-emitting element 10 by a wire 230. In addition, the first external electrode 213 and the second external electrode 214 may reflect light emitted from the light-emitting element 10 to improve light extraction efficiency and dissipate heat of the light-emitting element 10 to outside. The light-emitting element 10 may be the light-emitting element 1C shown in FIG. 8. Further referring to FIG. 8, the conductive substrate 107 of the light-emitting element 1C is mounted on the second external electrode 214, and the wire 230 connects the first electrode structure 101 to the first external electrode 213. The light-emitting package 1P may be applied to a backlight unit, a lighting unit, a display device, an indicator, a lamp, a street lamp, a lighting device for a vehicle, a display device for a vehicle, or a smart watch, but is not limited thereto.

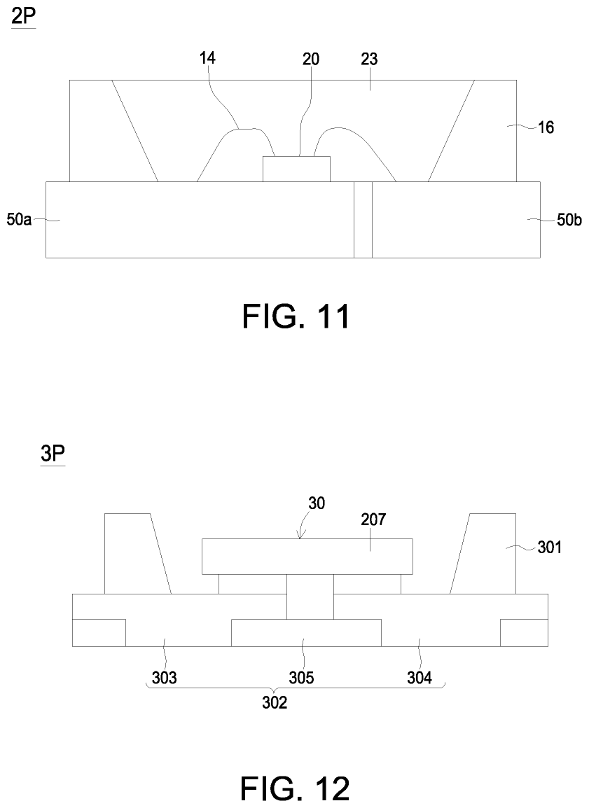

FIG. 11 shows a schematic cross-sectional view of a light-emitting package 2P in accordance with an embodiment of the present application. As shown in FIG. 11, the light-emitting package 2P includes a body 16, a first terminal 50a and second terminal 50b disposed in the body 16, a light-emitting element 20, wires 14, and a packaging material 23. In an embodiment, the inner sidewall of the body 16 may include a reflective structure. In the chamber, the first terminal 50a and the second terminal 50b are spaced apart from each other. The light-emitting element 20 is disposed on at least one of the first and second terminals 50a and 50b. For example, the light-emitting element 20 can be disposed on the first terminal 50a, and the first electrode structure 201 (shown in FIG. 9) and the second electrode structure 208 (shown in FIG. 9) of the light-emitting element are electrically connected to the first and second terminals 50a and 50b by the wires. The packaging material 23 covers the light-emitting element 20. The packaging material 23 includes, for example, silicon or epoxy resin, and the structure thereof can be single layer or multi-layer. In an embodiment, the packaging material 23 may further include a wavelength conversion material, such as phosphor and/or a scattering material, for converting the wavelength of the light generated by the light-emitting element 20. The light-emitting element 20 may be the light-emitting element 2C in FIG. 9. The light-emitting package 2P may be applied to a backlight unit, a lighting unit, a display device, an indicator, a lamp, a street lamp, a lighting device for a vehicle, a display device for a vehicle, or a smart watch, but is not limited thereto.

FIG. 12 shows a schematic diagram of the light-emitting package 3P in accordance with an embodiment of the present application. Referring to FIG. 12, a light-emitting element 30 is mounted on first bonding pad 303 and a second bonding pad 304 of a package substrate 302 in a flip-chip form. The first bonding pad 303 and the second bonding pad 304 are electrically insulated by an insulative portion 305 including insulative material. In flip-chip mounting, the side of the carrier 207 opposite to the surface where the pads are formed faces upward, and the side of the carrier 207 is the main light extraction surface. Disposing an encapsulation wall 301 around the light-emitting element 30 can increase the light extraction efficiency of the light-emitting device package 3P, wherein the light-emitting element 30 can be the light-emitting elements in the foregoing embodiments. The light-emitting package 3P may be applied to a backlight unit, a lighting unit, a display device, an indicator, a lamp, a street lamp, a lighting device for a vehicle, a display device for a vehicle, or a smart watch, but is not limited thereto.

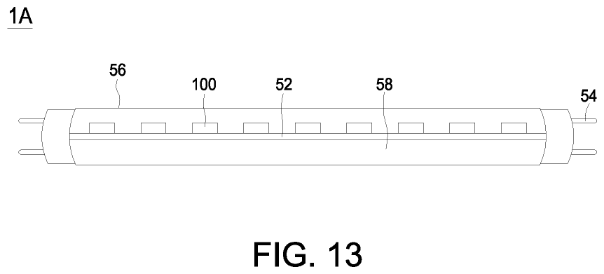

FIG. 13 shows a schematic cross-sectional view of a light-emitting device 1A in accordance with an embodiment of the present application. The light-emitting device 1A includes a plurality of light-emitting devices 100 mounted on a circuit board 52 in a shape of long-flat plate. The plurality of light-emitting devices 100 is disposed on one side of the circuit board 52 and arranged at intervals from each other along the longitudinal direction of the circuit board 52. On the other side of the circuit board 52, a heatsink 58 is provided to dissipate the heat generated by the light-emitting devices 100. On the side where the light-light-emitting devices 100 are mounted, a transparent cover 56 made of a material that can be easily passed through by emitted-light of the light-emitting devices 100 is provided. In addition, for providing electric power to the circuit board 52, terminals 54 are provided at both ends of the light-emitting device 1A to connect to a power source (not shown). The light-emitting devices 100 may be the light-emitting element 1C, 2C or the light-emitting packages 1P, 2P, 3P of the foregoing embodiments.

It is noted that each of the embodiments listed in the present application is merely used to describe the present application, not limiting the scope of the present application. It will be apparent to any one that obvious modifications or variations can be made to the devices in accordance with the present disclosure without departing from the spirit and scope of the present application. Identical or similar components in different embodiments or the components having identical reference numerals in different embodiments have identical physical properties or chemical properties. In addition, under suitable circumstances, the above-mentioned embodiments in the present application may be combined or replaced with each other, not limiting to the specific embodiments described above. In an embodiment, the connecting relationship of the specific component and other component described in detail may also be applied into other embodiments, falling within the scope of the following claims and their equivalents of the present application.

What is claimed is:

1. A semiconductor stack, comprising:
a first semiconductor structure;
a second semiconductor structure; and
an active structure between the first semiconductor structure and the second semiconductor structure, wherein the active structure comprises:
a first well set disposed on the first semiconductor structure and comprising one or multiple first wells;
a second well set disposed between the first well set and the second semiconductor structure and comprising one or multiple second wells; and
a plurality of barriers, arranged alternately with the one or multiple first wells and the one or multiple second wells;
wherein each first well has a first thickness, and each second well has a second thickness different from the first thickness, and the one or the multiple first wells and the one or the multiple second wells comprise AlₓIn_{y}Ga_{1-x-y}N respectively, wherein 0≤x≤1, 0≤y≤1, 0≤1−x−y<1.

2. The semiconductor stack of claim 1, wherein the second thickness is greater than the first thickness.

3. The semiconductor stack of claim 2, wherein a difference between the second thickness and the first thickness is 1% to 70% of the second thickness.

4. The semiconductor stack of claim 3, wherein the active structure emits a light with a wavelength between 420 nm and 460 nm, and the difference between the second thickness and the first thickness is 1% to 10% of the second thickness.

5. The semiconductor stack of claim 3, wherein the active structure emits a light with a wavelength between 350 nm and 400 nm, and the difference between the second thickness and the first thickness is 3% to 20% of the second thickness.

6. The semiconductor stack of claim 2, wherein the active structure further comprises a last well disposed between the second well set and the second semiconductor structure, and the last well has a third thickness less than the first thickness or the second thickness, and a material of the last well comprises AlₓIn_{y}Ga_{1-x-y}N, 0≤x≤1, 0≤y≤1, 0≤1−x−y<1.

7. The semiconductor stack of claim 6, wherein the active structure emits a light with a wavelength between 420 nm and 460 nm.

8. The semiconductor stack of claim 2, wherein a number of the multiple second wells is greater than that of the multiple first wells.

9. The semiconductor stack of claim 1, wherein a number of the multiple second wells is greater than that of the multiple first wells.

10. The semiconductor stack of claim 9, wherein the first thicknesses of the multiple first wells are the same.

11. The semiconductor stack of claim 9, wherein the second thicknesses of the multiple second wells are the same.

12. The semiconductor stack of claim 9, wherein thicknesses of the multiple first wells gradually are increased along a direction from the first semiconductor structure toward the second semiconductor structure.

13. The semiconductor stack of claim 9, wherein thicknesses of the multiple second wells gradually increase along a direction from the first semiconductor structure toward the second semiconductor structure.

14. The semiconductor stack of claim 1, further comprising one or multiple V-shaped recesses.

15. The semiconductor stack of claim 14, wherein the active structure emits a light with a wavelength between 320 nm and 400 nm, and the one V-shaped recess or each of the multiple V-shaped recesses comprises a bottom in the active structure.

16. The semiconductor stack of claim 14, wherein the active structure emits a light with a wavelength between 380 nm and 460 nm, and the one V-shaped recess or each of the multiple V-shaped recesses comprises a bottom in the active structure.

17. A light-emitting element, comprising:
the semiconductor stack of claim 1; and
a first electrode structure, electrically connecting to the first semiconductor structure.

18. A light-emitting package, comprising:
an encapsulation substrate, comprising a first external electrode and a second external electrode insulated from the first external electrode;
the light-emitting element of claim 17, wherein the light-emitting element further comprises a conductive substrate electrically connecting to the second semiconductor structure and mounted on the second external electrode; and
a wire, connecting the first electrode structure to the first external electrode.

19. A light-emitting package, comprising:
a package substrate, comprising a first bonding pad and a second bonding pad; and
the light-emitting element of claim 17, wherein the light-emitting element further comprises a second electrode structure electrically connecting to the second semiconductor structure, and the first electrode structure and the second electrode structure respectively connects to the first bonding pad and the second bonding pad of the package substrate, thereby mounting the light-emitting element on the package substrate in a flip-chip form.

20. A light-emitting device, comprising:
a circuit board;
a plurality of light-emitting elements of claim 17, disposed on one side of the circuit board; and
a transparent cover, disposed on the side of the circuit board where the plurality of light-emitting elements is mounted to cover the plurality of light-emitting elements.
